(19) United States
(12) Patent Application Publication
(10) Pub. No.: US 2023/0137619 A1
(43) Pub. Date: May 4, 2023

(54) COIL STRUCTURE TO CONTROL VIA IMPEDANCE

(71) Applicant: Intel Corporation, Santa Clara, CA (US)

(72) Inventors: Landon HANKS, Milwaukie, OR (US); Xiang LI, Portland, OR (US)

(21) Appl. No.: 18/088,460

(22) Filed: Dec. 23, 2022

(51) Int. Cl. H05K 1/02; H05K 1/11; H05K 1/16; G06F 1/18

(52) U.S. Cl. CPC H05K 1/0216; H05K 1/115; H05K 1/165; G06F 1/189; H05K 2201/095

(57) ABSTRACT

A circuit board includes vias with a coil structure. A circuit board includes vias with barrels that extend vertically through the circuit board and pads in different planes of the circuit board, such as the top surface and bottom surface, and optionally in an inner routing layer. The coil structure is a coil of conductor in a plane of the circuit board, electrically connected to a pad in that plane, which is electrically connected to the barrel. The coil structure provides self-inductance around the pad, which brings up the reactive impedance of the via to balance the capacitive reactance of the via.

### TECHNICAL FIELD

Descriptions are generally related to electronics, and more particular descriptions are related to circuit board structures.

### BACKGROUND OF THE INVENTION

Circuit boards (e.g., printed circuit boards (PCBs)) are significant in electronic devices. Circuit boards enable the interconnection of discrete electronic components. An example of a common application of components on a circuit board is a double data rate (DDR) memory board with memory devices to provide computer systems with system memory.

Circuit boards are often multilevel boards, with top and bottom surfaces as well as one or more inner layers. The top surface typically has mounting pads for components, as well as traces for signal routing. The bottom surface typically includes signal routing, and may also include mounting pads for components. The inner layers can have signal routing, ground planes, power planes, or a combination of signal routing and a ground plane or signal routing and a power plane.

Vias are critical components in circuit boards, enabling routing of traces between different layers of the board. In memory boards and other boards with high speed communication, the vias can have an impact on signal integrity. With increasing signal speeds, the vias affect characteristic impedance specifications on the signal channel interconnects, as they can have a capacitive reactive effect, pulling signal impedance out of alignment with specifications.

To reduce the impedance effect of the vias, the vias can be back drilled, making a hollow via with less conductive material. However, back drilling increases manufacturing costs. Additionally, back drilling is not applicable in all scenarios. Another option is the use of micro-vias having a barrel with a smaller diameter. However, micro-vias also increase manufacturing costs. Another option is anti-pad size modulation. However, anti-pad modulation alone does not provide enough control over impedance variance.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a circuit board with vias with coils.

FIGS. 2A-2C are representations of a via with a coil in the top surface and a coil in an inner routing layer.

FIGS. 3A-3C are representations of a via with a coil in the bottom surface and a coil in an inner routing layer.

FIGS. 4A-4C are representations of a via with a coil in the top surface.

FIGS. 5A-5C are representations of a via with a coil in an inner routing layer.

FIGS. 6A-6B are representations of a via with a coil in the top surface and a coil in a lower inner routing layer.

FIGS. 7A-7B are representations of a via with a coil in the bottom surface and a coil in an upper inner routing layer.

FIGS. 8A-8C are representations of a via with a coil and differing anti-pad sizing.

FIG. 9 is a flow diagram of an example of a process for creating a circuit board with coils.

FIG. 10 is a block diagram of an example of a computing system in which a circuit board with coils can be implemented.

FIG. 11 is a block diagram of an example of a mobile device in which a circuit board with coils can be implemented.

FIG. 12 is a block diagram of an example of a multi-node network in which a circuit board with coils can be implemented.

Descriptions of certain details and implementations follow, including non-limiting descriptions of the figures, which may depict some or all examples, and well as other potential implementations.

### DETAILED DESCRIPTION OF THE INVENTION

As described herein, a circuit board includes vias with a coil structure. A circuit board includes vias with barrels that extend vertically through the circuit board and pads in different planes of the circuit board, such as the top surface and bottom surface, and optionally in an inner routing layer. The coil structure is a coil of conductor in a plane of the circuit board, electrically connected to a pad in that plane, which is electrically connected to the barrel. The coil structure provides self-inductance around the pad, which brings up the reactive impedance of the via to balance the capacitive reactance of the via.

The coil in the plane of the pad represents a self-inductance structure. The self-inductance refers to the creation of inductive reactance based on the structure of the trace and pad with itself. The coil structure can induce inductive reactance in the signal line that can balance the capacitive inductance inherent in the via structure. Thus, the self-inductance structure provides the ability to vary the overall impedance of the via.

A via can include a pad in a plane of the circuit board, such as a pad in the top surface and a pad in the bottom surface. The via can include a pad in an inner routing layer where there is a trace to connect to the via. The via has a barrel, which is the part of the via that extends through the layers of the circuit board. The various layers of the board have an anti-pad region around the barrel of the via. The anti-pad region is a region of clearance around the pad within the layers, with a minimum distance between the barrel and either traces or conductor planes. While some variation of the via impedance is possible through the modulation of the anti-pad spacing, anti-pad modulation alone does not vary the via impedance as effectively as a self-inductance structure.

The use of a self-inductance structure such as a coil can improve the overall via impedance with lower cost than back drilling, and with more effective control than anti-pad modulation along. Coils can be used in addition to anti-pad modulation. Coils can be more applicable than back drilling. For example, in dual rank memory modules, back drilling may not be applicable, while coils can be used. Coils can also provide more effective impedance control than micro-vias.

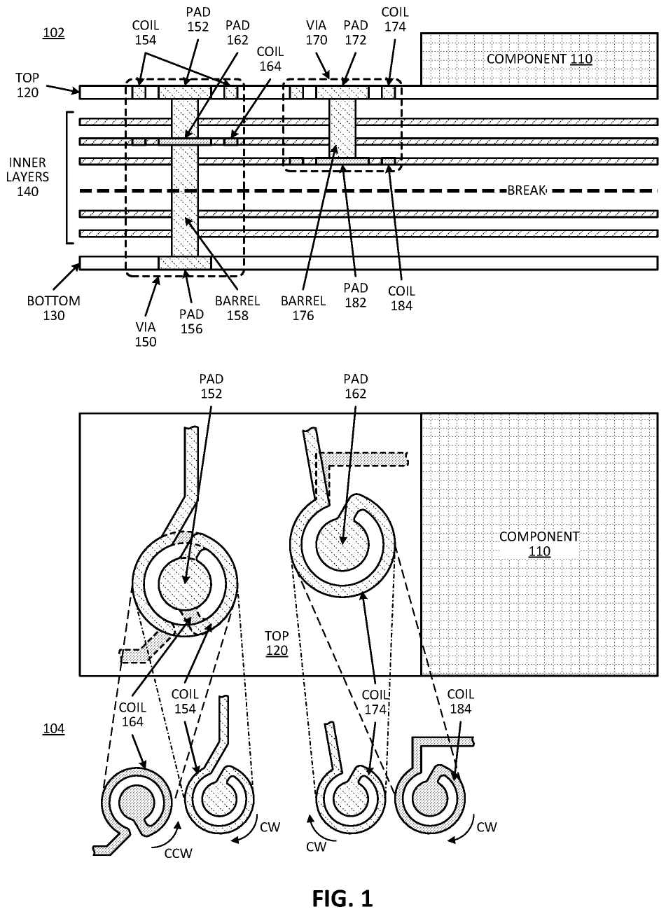

FIG. 1 is a block diagram of an example of a circuit board with vias with coils. View 102 illustrates a cutaway view of a multilayer circuit board, such as printed circuit board (PCB). View 104 illustrates a top view of a portion of the PCB illustrated in view 102. View 104 also illustrates a separation of the via coils. The features in the drawing are not necessarily to scale. It will be understood that features are illustrated for purposes of discussion rather than necessarily representing a practical implementation of the concepts.

View 102 illustrates a multilayer board, illustrating 5 inner layers, a top surface layer, and a bottom surface layer. While referred to as a “top surface” and a “bottom surface” for purposes of description, it will be understood that the top surface and the bottom surface refer to a top layer and a bottom layer, respectively, that have routing and mounting pads. The top surface can refer to a top layer of routing that is then covered by a PCB coating, such as a top layer of fiberglass. Similarly, the bottom surface can refer to a bottom layer of routing that is covered by a PCB coating, such as a bottom layer of fiberglass.

The top surface refers to a top layer of routing that is visible as the top visible surface of the PCB. The bottom surface refers to a bottom layer of routing that is visible as the bottom visible surface of the PCB. The inner layers are not visible through the top or bottom surfaces. Reference throughout to the top surface and to the bottom surface refer to these routing layers on the top and bottom of the PCB, respectively.

It will be understood that a PCB can have just the top surface and the bottom surface connected with vias, or can have the top surface, bottom surface, and one or more inner layers for routing and/or for ground planes or power planes. One of skill in the art will understand that PCBs are available with up to dozens of layers. The board can be referred to as a “board,” a “circuit board,” a “PCB,” or other designation. For simplicity, the expressions PCB and board will generally be used in the descriptions below. The board can have 2 layers (top and bottom surfaces) or multiple layers (up to dozens of layers).

Top 120 represents the top surface/layer of the PCB and bottom 130 represents the bottom surface/layer of the PCB. Inner layers 140 represent layers between top 120 and bottom 130. In general, the orientation of the PCB surface is typically an arbitrary designation relative to the mounting of the primary components, such as integrated circuits (ICs). It will be understood that components can be mounted on both the top and the bottom surfaces of the PCB.

Routing refers to the running of traces between electronic components, whether ICs, power components, passive components, or other electronic components. One or more layers of a multilayer PCB can have a power plane, referring to having as much of the layer free of trace routing as possible so the entire layer has a large area of conductor that is electrically connected to the power source. One or more layers of a multilayer PCB can have a ground plane, referring to having as much of the layer free of trace routing as possible so the entire layer has a large area of conductor that is electrically connected to the circuit ground. One or more layers can be routing layers, having routing between components. Component 110 represents an IC component mounted on the board.

Vias extend through the board to connect to traces and/or mounting pads in different layers. A via can extend through the entire board, from top 120 to bottom 130, as with via 150 having barrel 158. Barrel 158 represents the conductive tube that fills the hole drilled for via 150. The traces, planes, and vias in a PCB are commonly all made of copper or a copper alloy. Other metals can be used. The metal used can change the impedance and the inductive reactance of a coil/winding, as will be understood by one skilled in the art. A via can include a plane that connects the barrel to a component (e.g., if connected to a mounting pad), a trace, or a plane. Barrel 158 connects pad 152 of top 120 to pad 156 of bottom 130.

In one example, via 150 includes pad 162 on an inner layer to make an electrical connection in that layer. In one example, via 150 includes coil 154 in top 120 and coil 164 in the inner layer. Coil 154 and coil 164 represent windings within the plane of the layer around the respective pad. The winding provides self-inductance in the signal. Typically, the winding would be used to connect to signal traces or to a mounting pad for a signaling pin. The direct current (DC) nature of the power plane and ground plane would not need self-inductance to control the via impedance.

Via 170 represents a blind via, which extends from one of the outer surfaces through multiple inner layers, but not all the way through the board. Via 170 includes pad 172 in top 120 and pad 182 in an inner layer, connected by barrel 176. Via 170 includes coil 174 around pad 172 in top 120 and coil 184 around pad 182 in the inner layer.

View 104 illustrates a top view of the portion of the PCB, with component 110, via 150, and via 170. In view 104, coil 154 and coil 174 in top 120 can be seen curving around pad 152 and pad 172, respectively. Coil 164 is underneath coil 154 from a top view perspective. For purposes of illustration, coil 164 is shown having a different rotational pattern around pad 162 relative to coil 154 around pad 152. Coil 184 is underneath coil 174, and again for purposes of illustration, coil 184 is shown as being aligned with coil 174.

View 104 further illustrates coil 164 separated from coil 154 to illustrate that coils around the same via barrel can have different winding directions. More specifically, coil 164 is illustrated with a counterclockwise (CCW) winding while coil 154 is illustrated with a clockwise (CW) winding. It will be understood that the winding direction can be reversed for either coil 154, coil 164, or both coil 154 and coil 164.

View 104 illustrates coil 174 separated from coil 184 to illustrate that coils around the same via barrel can have the same winding direction. More specifically, coil 174 is illustrated with a clockwise winding as is coil 184. In one example, coils with the same winding direction can have the same coil length and the same starting point. In one example, coils with the same winding direction can have different coil lengths or can have different starting points or can have different coil lengths and different starting points.

In one specific example, stub-via impedance of dual inline memory module (DIMM) boards for memory was prone to drop below the 50 ohms specification for the signal line, especially on the signal lines of the command/address (CA) channel. The capacitive effects of the stub-vias at high-speed memory signaling was observed to drop the effective impedance down to approximately 40 ohms, which degrades signal performance. Implementing coils/windings as inductive elements in the signal line connections to the vias increased the inductive reactance, substantially countering the capacitive effects, bringing the overall impedance back to approximately the 50 ohms specification.

Both via 150 and via 170 are illustrated as having coils in two different planes of the PCB. In one example, a via in the PCB has only one plane with a coil, as opposed to coils in two planes. When a via has a single coil, the coil can be in the top surface, the bottom surface, or in an inner layer.

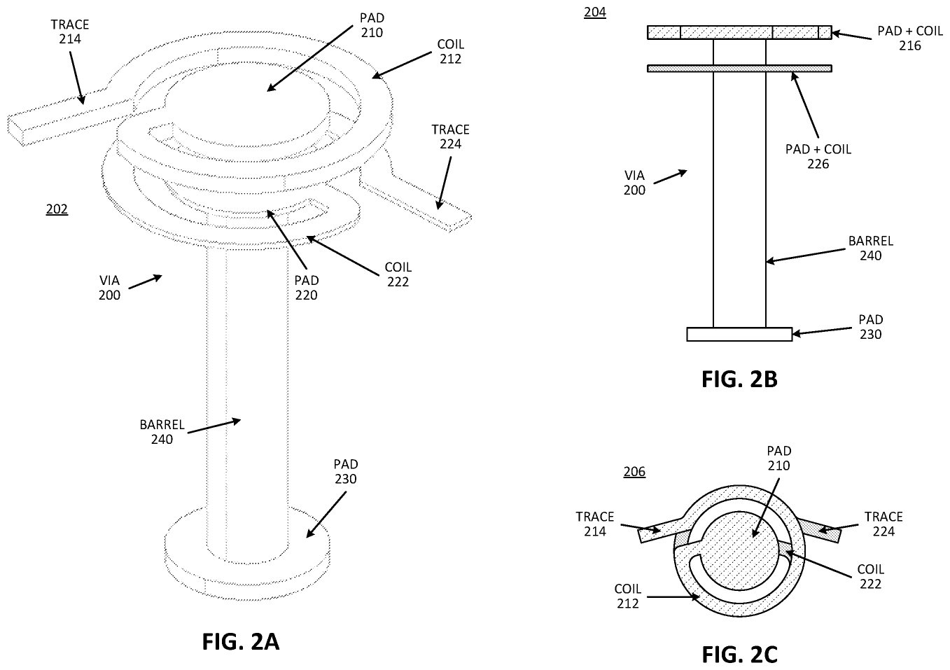

FIG. 2A is a representation of a perspective view of a via with a coil in the top surface and a coil in an inner routing layer. View 202 is a perspective view of via 200, which includes barrel 240 to extend through a PCB. Via 200 includes pad 210 in a top surface of the PCB and pad 230 in a bottom surface of the PCB. Via 200 includes pad 220 in an inner layer of the PCB.

Via 200 includes coil 212 around pad 210 in the top surface, providing a winding between the electrical connection of pad 210 to trace 214. Trace 214 represents a signal trace. Via 200 includes coil 222 around pad 220 in an inner layer, providing a winding between the electrical connection of pad 220 to trace 224. Trace 224 represents a signal trace in the inner layer. In one example, coil 212 is wound in the opposite direction of coil 222. In one example, coil 212 and coil 222 are wound in the same direction.

A coil can alternatively be referred to as an in-plane winding. Coil 212 is shown with approximately 360 radial degrees of winding. It will be understood that the winding can extend for fewer radial degrees. In one example, the winding extends for approximately 180 radial degrees or more. Varying the coil length and varying anti-pad size enable tuning the via characteristic impedance. Varying the coil length can control the self-inductance leading into the via pads. The coil can connect to the signal trace at any location and at any direction.

FIG. 2B is a representation of a side view of a via with a coil in the top surface and a coil in an inner routing layer. View 204 is a side view of via 200, illustrating barrel 240 extending from pad 230 to pad+coil 216. Pad+coil 216 represents a combination of pad 210 and coil 212. Pad+coil 226 represents a combination of pad 220 and coil 222, which also connects to barrel 240.

FIG. 2C is a representation of a top view of a via with a coil in the top surface and a coil in an inner routing layer. View 206 is a top view of via 200, illustrating coil 212 connected to, extending from, and wrapping around, pad 210. Instead of having trace 214 directly connect to pad 210, trace 214 connects to coil 212 leading into pad 210. From view 206, pad 220 is not visible as it is under pad 210. Portions of coil 222 can be seen, which connect to trace 224.

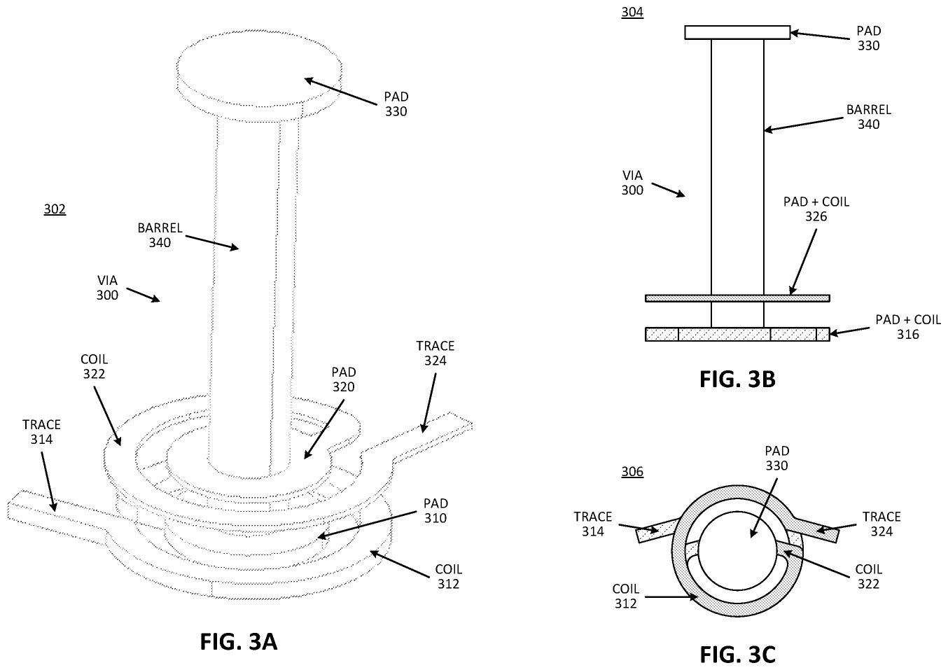

FIG. 3A is a representation of a perspective view of a via with a coil in the bottom surface and a coil in an inner routing layer. View 302 is a perspective view of via 300, which includes barrel 340 to extend through a PCB. Via 300 includes pad 310 in a bottom surface of the PCB and pad 330 in a top surface of the PCB. Via 300 includes pad 320 in an inner layer of the PCB.

Via 300 includes coil 312 around pad 310 in the bottom surface, providing a winding between the electrical connection of pad 310 to trace 314. Trace 314 represents a signal trace. Via 300 includes coil 322 around pad 320 in an inner layer, providing a winding between the electrical connection of pad 320 to trace 324. Trace 324 represents a signal trace in the inner layer. In one example, coil 312 is wound in the opposite direction of coil 322. In one example, coil 312 and coil 322 are wound in the same direction.

FIG. 3B is a representation of a side view of a via with a coil in the bottom surface and a coil in an inner routing layer. View 304 is a side view of via 300, illustrating barrel 340 extending from pad 330 to pad+coil 316. Pad+coil 316 represents a combination of pad 310 and coil 312. Pad coil 326 represents a combination of pad 320 and coil 322, which also connects to barrel 340.

FIG. 3C is a representation of a top view of a via with a coil in the bottom surface and a coil in an inner routing layer. View 306 is a top view of via 300, illustrating coil 322 connected to, extending from, and wrapping around, its pad, which is under pad 330. Instead of having trace 324 directly connect to pad 320, trace 324 connects to coil 322 leading into pad 320. From view 306, pad 320 and pad 310 are not visible as they are under pad 330. Portions of coil 312 can be seen, which connect to trace 314.

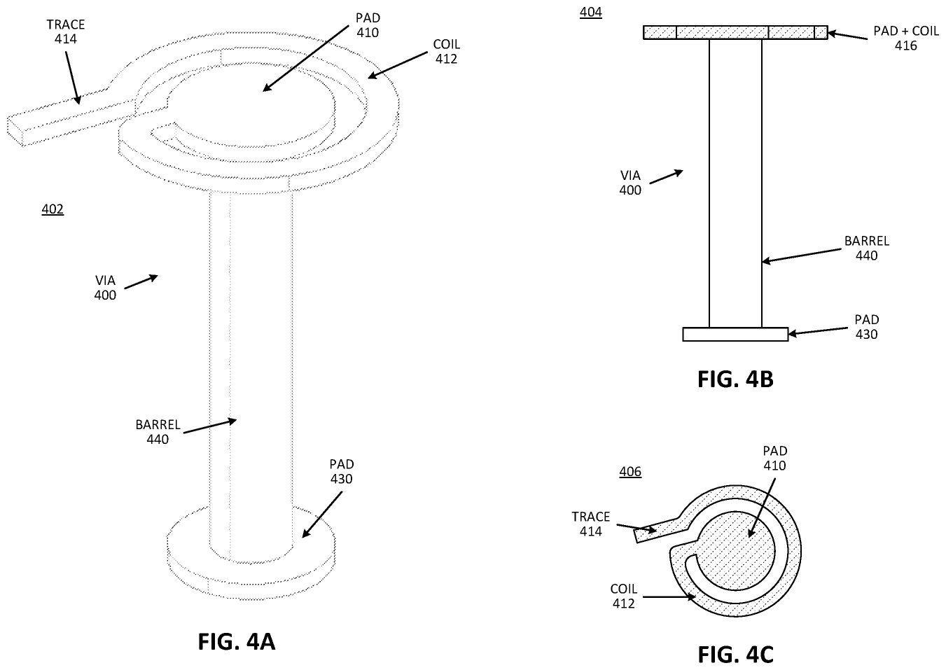

FIG. 4A is a representation of a perspective view of a via with a coil in the top surface. View 402 is a perspective view of via 400, which includes barrel 440 to extend through a PCB. Via 400 includes pad 410 in a top surface of the PCB and pad 430 in a bottom surface of the PCB.

Via 400 includes coil 412 around pad 410 in the top surface, providing a winding between the electrical connection of pad 410 to trace 414. Trace 414 represents a signal trace. Coil 412 can be wound in either direction. Alternatively to being in the top surface, via 400 could have a single coil in the bottom surface.

FIG. 4B is a representation of a side view of a via with a coil in the top surface. View 404 is a side view of via 400, illustrating barrel 440 extending from pad 430 to pad+coil 416. Pad+coil 416 represents a combination of pad 410 and coil 412.

FIG. 4C is a representation of a top view of a via with a coil in the top surface. View 406 is a top view of via 400, illustrating coil 412 connected to, extending from, and wrapping around, pad 410. Instead of having trace 414 directly connect to pad 410, trace 414 connects to coil 412 leading into pad 410.

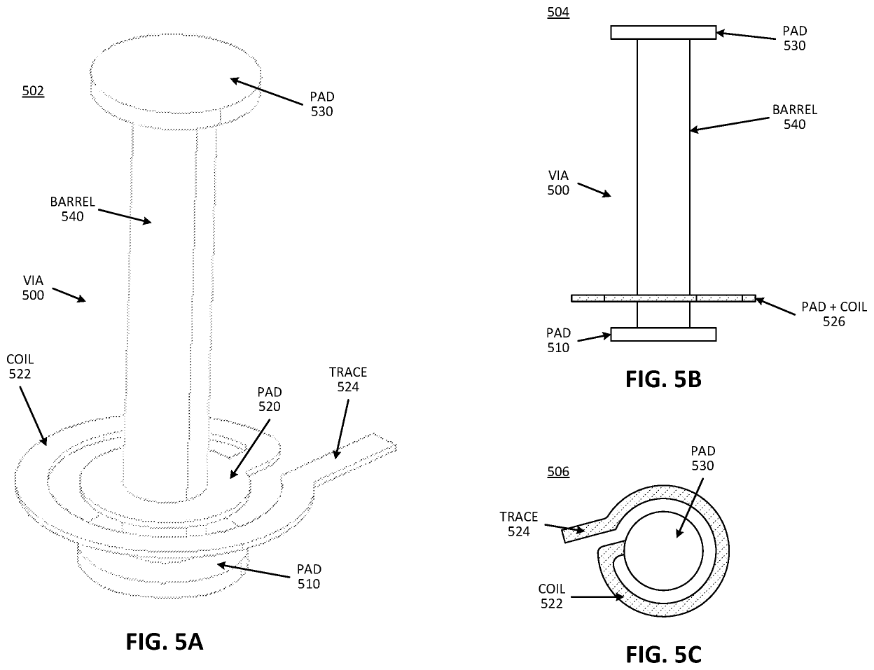

FIG. 5A is a representation of a perspective view of a via with a coil in an inner routing layer. View 502 is a perspective view of via 500, which includes barrel 540 to extend through a PCB. Via 500 includes pad 530 in a top surface of the PCB and pad 510 in a bottom surface of the PCB. Via 500 includes pad 520 in the inner layer of the PCB.

Via 500 includes coil 522 around pad 520 in the inner layer, providing a winding between the electrical connection of pad 520 to trace 524. Trace 524 represents a signal trace in the inner routing layer. Coil 522 can be wound in either direction.

FIG. 5B is a representation of a side view of a via with a coil in the inner layer. View 504 is a side view of via 500, illustrating barrel 540 extending from pad 530 to pad+coil 526. Pad+coil 526 represents a combination of pad 520 and coil 522.

FIG. 5C is a representation of a top view of a via with a coil in the inner layer. View 506 is a top view of via 500, illustrating coil 522 connected to, extending from, and wrapping around, pad 520, which is under pad 530 in view 506. Instead of having trace 524 directly connect to pad 520, trace 524 connects to coil 522 leading into pad 520.

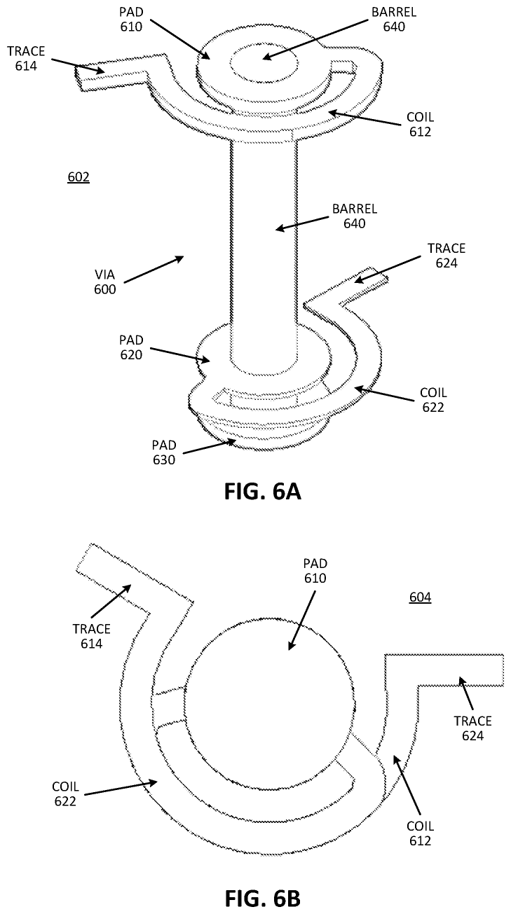

FIG. 6A is a representation of a perspective view of a via with a coil in the top surface and a coil in an inner routing layer. View 602 is a perspective view of via 600, which includes barrel 640 to extend through a PCB. Via 600 includes pad 610 in a top surface of the PCB and pad 630 in a bottom surface of the PCB. Via 600 includes pad 620 in an inner layer of the PCB. In previous views, the coil of the inner layer was a layer close to the outer surface that has the coil. In view 602, there is a coil in the top surface and in an inner layer near the bottom surface.

Via 600 includes coil 612 around pad 610 in the top surface, providing a winding between the electrical connection of pad 610 to trace 614. Trace 614 represents a signal trace. Via 600 includes coil 622 around pad 620 in an inner layer, providing a winding between the electrical connection of pad 620 to trace 624. Trace 624 represents a signal trace in the inner layer near pad 630 of the bottom surface. In one example, coil 612 is wound in the opposite direction of coil 622. In one example, coil 612 and coil 622 are wound in the same direction.

FIG. 6B is a representation of a top view of a via with a coil in the top surface and a coil in an inner routing layer. View 604 is a top view of via 600, illustrating coil 612 connected to, extending from, and wrapping around, pad 610. Instead of having trace 614 directly connect to pad 610, trace 614 connects to coil 612 leading into pad 610. From view 604, pad 620 is not visible as it is under pad 610. Portions of coil 622 can be seen, which connect to trace 624.

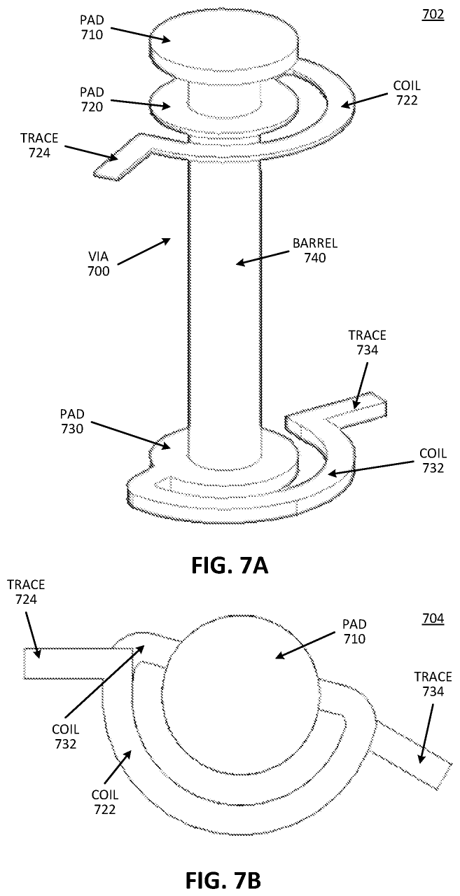

FIG. 7A is a representation of a perspective view of a via with a coil in the bottom surface and a coil in an inner routing layer. View 702 is a perspective view of via 700, which includes barrel 740 to extend through a PCB. Via 700 includes pad 730 in a bottom surface of the PCB and pad 710 in a top surface of the PCB. Via 700 includes pad 720 in an inner layer of the PCB. In previous views, the coil of the inner layer was a layer close to the outer surface that has the coil. In view 702, there is a coil in the bottom surface and in an inner layer near the top surface.

Via 700 includes coil 732 around pad 730 in the bottom surface, providing a winding between the electrical connection of pad 730 to trace 734. Trace 734 represents a signal trace. Via 700 includes coil 722 around pad 720 in an inner layer, providing a winding between the electrical connection of pad 720 to trace 724. Trace 724 represents a signal trace in the inner layer near pad 710 of the top surface. In one example, coil 732 is wound in the opposite direction of coil 722. In one example, coil 732 and coil 722 are wound in the same direction.

FIG. 7B is a representation of a top view of a via with a coil in the bottom surface and a coil in an inner routing layer. View 704 is a top view of via 700, illustrating coil 722 connected to, extending from, and wrapping around, its pad, which is under pad 710. Instead of having trace 724 directly connect to pad 720, trace 724 connects to coil 722 leading into pad 720. From view 704, pad 720 and pad 730 are not visible as they are under pad 710. Portions of coil 732 can be seen, which connect to trace 734.

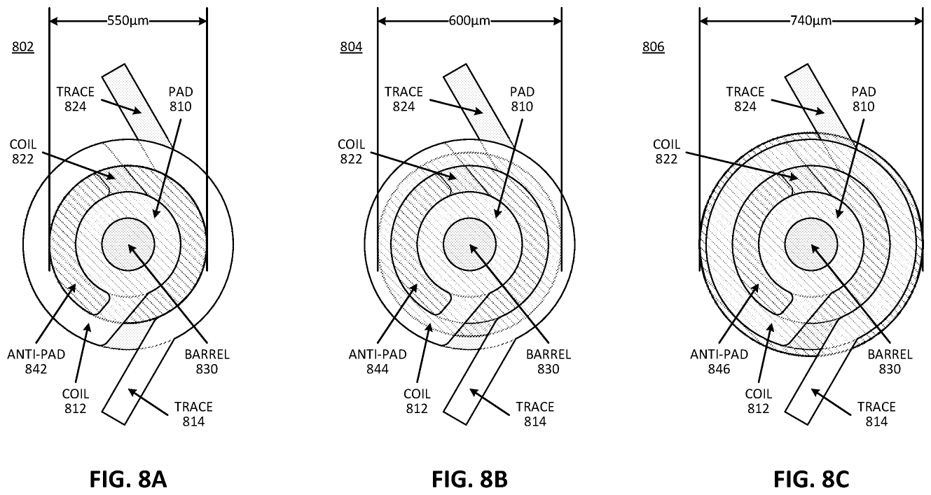

FIGS. 8A-8C are representations of a via with a coil and differing anti-pad sizing. Anti-pad size variation refers to a change in the negative space around the via/via pad in the layers of the PCB. Increasing the spacing around the via, the anti-pad size, reduces the capacitive effect of the via which improves the via impedance. Reduction of the capacitive effect reduces the drag-down of the via impedance. Including the coil/winding around the via pad increases reactive impedance, which can reverse the capacitive effect.

FIG. 8A provides a representation of a via with a coil with the anti-pad at a first size. The specific sizings provided for illustration can be for an example of a DIMM board. Other PCBs can have different absolute sizes and different relative sizes. Via 802 has an anti-pad size of approximately 550 microns (μm). As illustrated, the anti-pad has a diameter approximately equal to an inner diameter of the coil.

Barrel 830 extends through the board. Via 802 includes pad 810 in a top surface with coil 812 around pad 810, connecting the pad to trace 814. It will be understood that trace 814 can connect to coil 812 at any angle. In one example, via 802 includes a second layer with a coil, such as an inner layer. The other layer includes coil 822 connecting trace 824 to a pad not visible in the diagram. Anti-pad 842 represents the anti-pad sizing. 550 μm can represent a typical spacing around a via for one PCB architecture.

FIG. 8B provides a representation of a via with a coil with the anti-pad at a second size. Via 804 has an anti-pad size of approximately 600 μm. As illustrated, the anti-pad has a diameter of a size between the inner diameter and the outer diameter of the coil.

Barrel 830 extends through the board. Via 804 includes pad 810 in a top surface with coil 812 around pad 810, connecting the pad to trace 814. It will be understood that trace 814 can connect to coil 812 at any angle. In one example, via 804 includes a second layer with a coil, such as an inner layer. The other layer includes coil 822 connecting trace 824 to a pad not visible in the diagram. Anti-pad 844 represents the anti-pad providing 600 μm spacing around the via. The larger anti-pad can decrease in-plane capacitance and result in less impedance drop in response to a high-speed signal on the traces. The coils provide additional via impedance control.

FIG. 8C provides a representation of a via with a coil with the anti-pad at a second size. Via 806 has an anti-pad size of approximately 740 μm. As illustrated, the anti-pad has a diameter of a size larger than the outer diameter of the coil.

Barrel 830 extends through the board. Via 806 includes pad 810 in a top surface with coil 812 around pad 810, connecting the pad to trace 814. It will be understood that trace 814 can connect to coil 812 at any angle. In one example, via 806 includes a second layer with a coil, such as an inner layer. The other layer includes coil 822 connecting trace 824 to a pad not visible in the diagram. Anti-pad 846 represents the anti-pad providing 740 μm spacing around the via. The larger anti-pad in combination with the coil has the potential to overshoot the impedance response, creating an impedance higher than the specification. The combination of coil and anti-pad sizing can provide control over the via impedance.

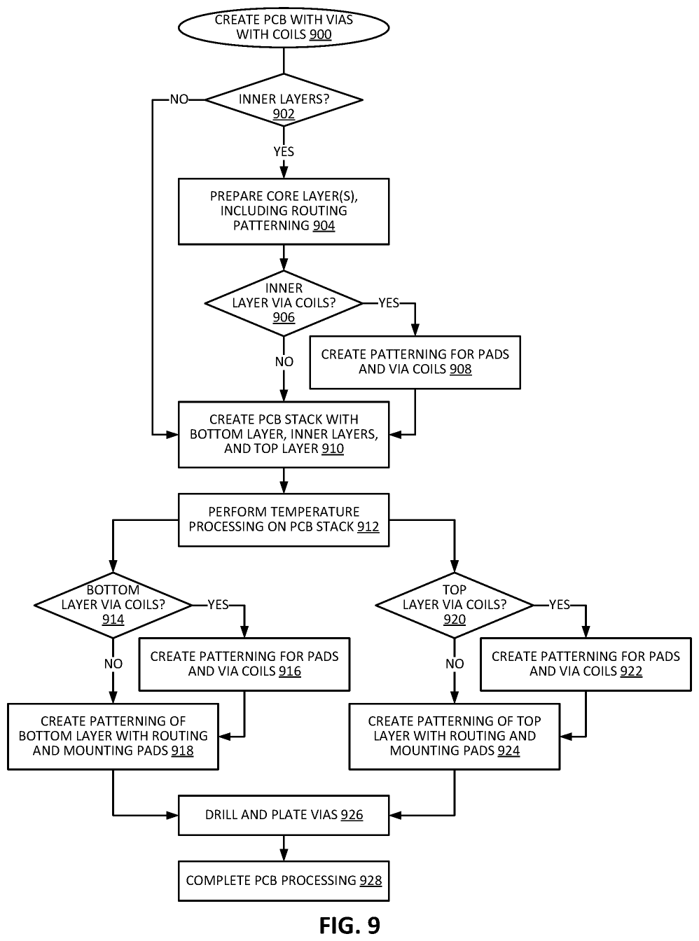

FIG. 9 is a flow diagram of an example of a process for creating a circuit board with coils. Process 900 represents a process to create a PCB with vias with coils to control the via impedance.

In one example, the PCB is a multilayer board. If there are inner layers, at 902 YES branch, the processing prepares one or more core layers, including routing patterning, at 904. If there are no inner layers, at 902 NO branch, the processing skips to the processing of the outer layers, being the top and bottom layers.

If there are via coils in any plane of an inner layer, at 906 YES branch, the processing creates the patterning for pads and via coils. The patterning refers to creation of trace and pad patterns of conductor in the inner layer. The conductor of the top layer, the bottom layer, and the inner layers are often made of copper. Other conductors could be used.

If there are no via coils in an inner plane, at 906 NO branch, the processing creates the PCB stack with bottom layer, zero or more inner layers, and the top layer, at 910. The processing can create the PCB stack, at 910, if there are no inner layers, at 902 NO branch, and after creation of patterning for pads and via coils, at 908, when there are inner layers with via coils. The stack includes the patterned conductor layered with structural layers, typically fiberglass, that bind the conductor layers together.

The processing can perform temperature processing on the PCB stack, at 912, which includes heating the PCB stack to turn the separate layers into a combined board, binding the layers together. If there are bottom layer via coils, at 914 YES branch, the processing can create patterning for pads and via coils in the bottom layer, at 916. If there are no bottom layer via coils, at 914 NO branch, or after creating the patterning on the bottom layer for via coils, the processing can create patterning of the bottom layer with routing and mounting pads, at 918.

If there are top layer via coils, at 920 YES branch, the processing can create patterning for pads and via coils in the top layer, at 922. If there are no top layer via coils, at 920 NO branch, or after creating the patterning on the top layer for via coils, the processing can create patterning of the top layer with routing and mounting pads, at 924. After creating the patterning in the bottom layer and the top layer, including optional via coils, the processing can perform drilling and plating of the vias, at 926. The processing can then complete the PCB processing, at 928.

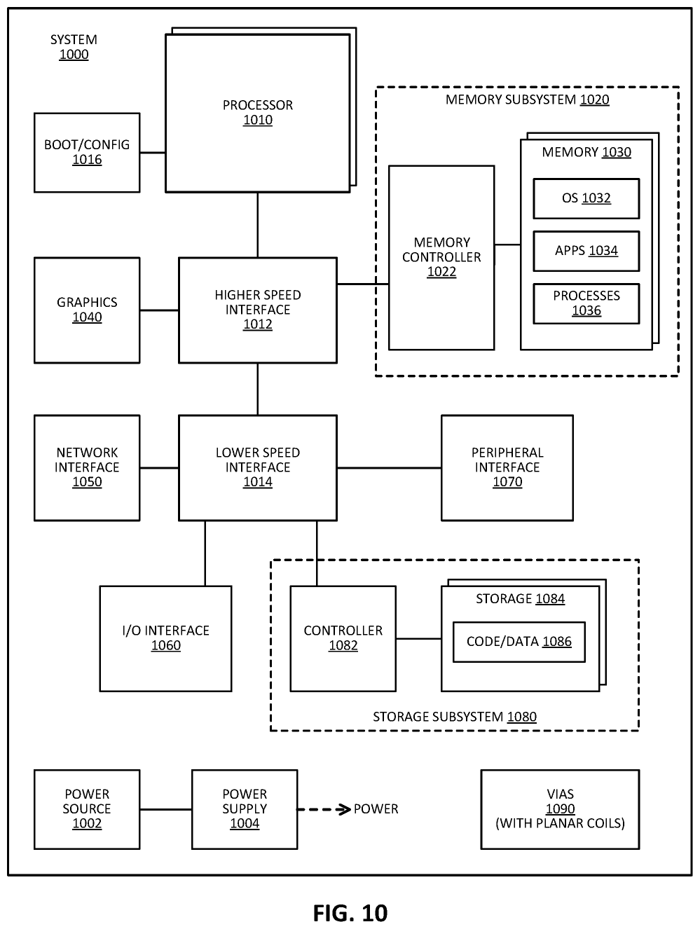

FIG. 10 is a block diagram of an example of a computing system in which a circuit board with coils can be implemented. System 1000 represents a computing device in accordance with any example herein, and can be a laptop computer, a desktop computer, a tablet computer, a server, a gaming or entertainment control system, embedded computing device, or other electronic device.

System 1000 represents a computer system that includes one or more electronic chips or integrated circuit devices with PCBs that include vias 1090 with planar coils in accordance with any example herein. In one example, memory subsystem 1020 includes one or more PCBs that have vias 1090. Thus, system 1000 can be a system with a host processor and a memory module (e.g., a DIMM) having multiple memory devices disposed on it, where the module PCB has vias with planar coils to control via impedance. Any other subsystem or component in system 1000 that performs signaling can have a PCB with vias 1090.

System 1000 includes processor 1010 can include any type of microprocessor, central processing unit (CPU), graphics processing unit (GPU), processing core, or other processing hardware, or a combination, to provide processing or execution of instructions for system 1000. Processor 1010 can be a host processor device. Processor 1010 controls the overall operation of system 1000, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1000 includes boot/config 1016, which represents storage to store boot code (e.g., basic input/output system (BIOS)), configuration settings, security hardware (e.g., trusted platform module (TPM)), or other system level hardware that operates outside of a host OS. Boot/config 1016 can include a nonvolatile storage device, such as read-only memory (ROM), flash memory, or other memory devices.

In one example, system 1000 includes interface 1012 coupled to processor 1010, which can represent a higher speed interface or a high throughput interface for system components that need higher bandwidth connections, such as memory subsystem 1020 or graphics interface components 1040. Interface 1012 represents an interface circuit, which can be a standalone component or integrated onto a processor die. Interface 1012 can be integrated as a circuit onto the processor die or integrated as a component on a system on a chip. Where present, graphics interface 1040 interfaces to graphics components for providing a visual display to a user of system 1000. Graphics interface 1040 can be a standalone component or integrated onto the processor die or system on a chip. In one example, graphics interface 1040 can drive a high definition (HD) display or ultra high definition (UHD) display that provides an output to a user. In one example, the display can include a touchscreen display. In one example, graphics interface 1040 generates a display based on data stored in memory 1030 or based on operations executed by processor 1010 or both.

Memory subsystem 1020 represents the main memory of system 1000, and provides storage for code to be executed by processor 1010, or data values to be used in executing a routine. Memory subsystem 1020 can include one or more varieties of random-access memory (RAM) such as DRAM, 3DXP (three-dimensional crosspoint), or other memory devices, or a combination of such devices. Memory 1030 stores and hosts, among other things, operating system (OS) 1032 to provide a software platform for execution of instructions in system 1000. Additionally, applications 1034 can execute on the software platform of OS 1032 from memory 1030. Applications 1034 represent programs that have their own operational logic to perform execution of one or more functions. Processes 1036 represent agents or routines that provide auxiliary functions to OS 1032 or one or more applications 1034 or a combination. OS 1032, applications 1034, and processes 1036 provide software logic to provide functions for system 1000. In one example, memory subsystem 1020 includes memory controller 1022, which is a memory controller to generate and issue commands to memory 1030. It will be understood that memory controller 1022 could be a physical part of processor 1010 or a physical part of interface 1012. For example, memory controller 1022 can be an integrated memory controller, integrated onto a circuit with processor 1010, such as integrated onto the processor die or a system on a chip.

While not specifically illustrated, it will be understood that system 1000 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1000 includes interface 1014, which can be coupled to interface 1012. Interface 1014 can be a lower speed interface than interface 1012. In one example, interface 1014 represents an interface circuit, which can include standalone components and integrated circuitry. In one example, multiple user interface components or peripheral components, or both, couple to interface 1014. Network interface 1050 provides system 1000 the ability to communicate with remote devices (e.g., servers or other computing devices) over one or more networks. Network interface 1050 can include an Ethernet adapter, wireless interconnection components, cellular network interconnection components, USB (universal serial bus), or other wired or wireless standards-based or proprietary interfaces. Network interface 1050 can exchange data with a remote device, which can include sending data stored in memory or receiving data to be stored in memory.

In one example, system 1000 includes one or more input/output (I/O) interface(s) 1060. I/O interface 1060 can include one or more interface components through which a user interacts with system 1000 (e.g., audio, alphanumeric, tactile/touch, or other interfacing). Peripheral interface 1070 can include any hardware interface not specifically mentioned above. Peripherals refer generally to devices that connect dependently to system 1000. A dependent connection is one where system 1000 provides the software platform or hardware platform or both on which operation executes, and with which a user interacts.

In one example, system 1000 includes storage subsystem 1080 to store data in a nonvolatile manner. In one example, in certain system implementations, at least certain components of storage 1080 can overlap with components of memory subsystem 1020. Storage subsystem 1080 includes storage device(s) 1084, which can be or include any conventional medium for storing large amounts of data in a nonvolatile manner, such as one or more magnetic, solid state, NAND, 3DXP, or optical based disks, or a combination. Storage 1084 holds code or instructions and data 1086 in a persistent state (i.e., the value is retained despite interruption of power to system 1000). Storage 1084 can be generically considered to be a “memory,” although memory 1030 is typically the executing or operating memory to provide instructions to processor 1010. Whereas storage 1084 is nonvolatile, memory 1030 can include volatile memory (i.e., the value or state of the data is indeterminate if power is interrupted to system 1000). In one example, storage subsystem 1080 includes controller 1082 to interface with storage 1084. In one example controller 1082 is a physical part of interface 1014 or processor 1010, or can include circuits or logic in both processor 1010 and interface 1014.

Power source 1002 provides power to the components of system 1000. More specifically, power source 1002 typically interfaces to one or multiple power supplies 1004 in system 1000 to provide power to the components of system 1000. In one example, power supply 1004 includes an AC to DC (alternating current to direct current) adapter to plug into a wall outlet. Such AC power can be renewable energy (e.g., solar power) power source 1002. In one example, power source 1002 includes a DC power source, such as an external AC to DC converter. In one example, power source 1002 or power supply 1004 includes wireless charging hardware to charge via proximity to a charging field. In one example, power source 1002 can include an internal battery or fuel cell source.

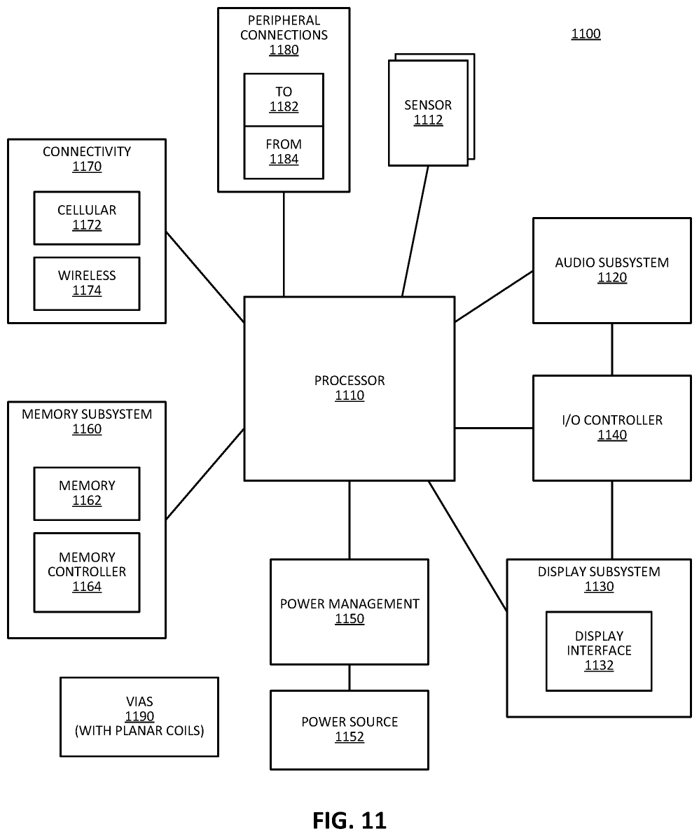

FIG. 11 is a block diagram of an example of a mobile device in which a circuit board with coils can be implemented. System 1100 represents a mobile computing device, such as a computing tablet, a mobile phone or smartphone, wearable computing device, or other mobile device, or an embedded computing device. It will be understood that certain of the components are shown generally, and not all components of such a device are shown in system 1100.

System 1100 represents a computer system that includes one or more electronic chips or integrated circuit devices with PCBs that include vias 1190 with planar coils in accordance with any example herein. In one example, memory subsystem 1120 includes one or more PCBs that have vias 1190. Any other subsystem or component in system 1100 that performs signaling can have a PCB with vias 1190.

System 1100 includes processor 1110, which performs the primary processing operations of system 1100. Processor 1110 can be a host processor device. Processor 1110 can include one or more physical devices, such as microprocessors, application processors, microcontrollers, programmable logic devices, or other processing means. The processing operations performed by processor 1110 include the execution of an operating platform or operating system on which applications and device functions are executed. The processing operations include operations related to I/O (input/output) with a human user or with other devices, operations related to power management, operations related to connecting system 1100 to another device, or a combination. The processing operations can also include operations related to audio I/O, display I/O, or other interfacing, or a combination. Processor 1110 can execute data stored in memory. Processor 1110 can write or edit data stored in memory.

In one example, system 1100 includes one or more sensors 1112. Sensors 1112 represent embedded sensors or interfaces to external sensors, or a combination. Sensors 1112 enable system 1100 to monitor or detect one or more conditions of an environment or a device in which system 1100 is implemented. Sensors 1112 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1112 can also include sensors for biometric systems such as fingerprint recognition systems, face detection or recognition systems, or other systems that detect or recognize user features. Sensors 1112 should be understood broadly, and not limiting on the many different types of sensors that could be implemented with system 1100. In one example, one or more sensors 1112 couples to processor 1110 via a frontend circuit integrated with processor 1110. In one example, one or more sensors 1112 couples to processor 1110 via another component of system 1100.

In one example, system 1100 includes audio subsystem 1120, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 1100, or connected to system 1100. In one example, a user interacts with system 1100 by providing audio commands that are received and processed by processor 1110.

Display subsystem 1130 represents hardware (e.g., display devices) and software components (e.g., drivers) that provide a visual display for presentation to a user. In one example, the display includes tactile components or touchscreen elements for a user to interact with the computing device. Display subsystem 1130 includes display interface 1132, which includes the particular screen or hardware device used to provide a display to a user. In one example, display interface 1132 includes logic separate from processor 1110 (such as a graphics processor) to perform at least some processing related to the display. In one example, display subsystem 1130 includes a touchscreen device that provides both output and input to a user. In one example, display subsystem 1130 includes a high definition (HD) or ultra-high definition

(UHD) display that provides an output to a user. In one example, display subsystem includes or drives a touchscreen display. In one example, display subsystem 1130 generates display information based on data stored in memory or based on operations executed by processor 1110 or both.

I/O controller 1140 represents hardware devices and software components related to interaction with a user. I/O controller 1140 can operate to manage hardware that is part of audio subsystem 1120, or display subsystem 1130, or both. Additionally, I/O controller 1140 illustrates a connection point for additional devices that connect to system 1100 through which a user might interact with the system. For example, devices that can be attached to system 1100 might include microphone devices, speaker or stereo systems, video systems or other display device, keyboard or keypad devices, buttons/switches, or other I/O devices for use with specific applications such as card readers or other devices.

As mentioned above, I/O controller 1140 can interact with audio subsystem 1120 or display subsystem 1130 or both. For example, input through a microphone or other audio device can provide input or commands for one or more applications or functions of system 1100. Additionally, audio output can be provided instead of or in addition to display output. In another example, if display subsystem includes a touchscreen, the display device also acts as an input device, which can be at least partially managed by I/O controller 1140. There can also be additional buttons or switches on system 1100 to provide I/O functions managed by I/O controller 1140.

In one example, I/O controller 1140 manages devices such as accelerometers, cameras, light sensors or other environmental sensors, gyroscopes, global positioning system (GPS), or other hardware that can be included in system 1100, or sensors 1112. The input can be part of direct user interaction, as well as providing environmental input to the system to influence its operations (such as filtering for noise, adjusting displays for brightness detection, applying a flash for a camera, or other features).

In one example, system 1100 includes power management 1150 that manages battery power usage, charging of the battery, and features related to power saving operation. Power management 1150 manages power from power source 1152, which provides power to the components of system 1100. In one example, power source 1152 includes an AC to DC (alternating current to direct current) adapter to plug into a wall outlet. Such AC power can be renewable energy (e.g., solar power, motion based power). In one example, power source 1152 includes only DC power, which can be provided by a DC power source, such as an external AC to DC converter. In one example, power source 1152 includes wireless charging hardware to charge via proximity to a charging field. In one example, power source 1152 can include an internal battery or fuel cell source.

Memory subsystem 1160 includes memory device(s) 1162 for storing information in system 1100. Memory subsystem 1160 can include nonvolatile (state does not change if power to the memory device is interrupted) or volatile (state is indeterminate if power to the memory device is interrupted) memory devices, or a combination. Memory 1160 can store application data, user data, music, photos, documents, or other data, as well as system data (whether long-term or temporary) related to the execution of the applications and functions of system 1100. In one example, memory subsystem 1160 includes memory controller 1164 (which could also be considered part of the control of system 1100, and could potentially be considered part of processor 1110). Memory controller 1164 includes a scheduler to generate and issue commands to control access to memory device 1162.

Connectivity 1170 includes hardware devices (e.g., wireless or wired connectors and communication hardware, or a combination of wired and wireless hardware) and software components (e.g., drivers, protocol stacks) to enable system 1100 to communicate with external devices. The external device could be separate devices, such as other computing devices, wireless access points or base stations, as well as peripherals such as headsets, printers, or other devices. In one example, system 1100 exchanges data with an external device for storage in memory or for display on a display device. The exchanged data can include data to be stored in memory, or data already stored in memory, to read, write, or edit data.

Connectivity 1170 can include multiple different types of connectivity. To generalize, system 1100 is illustrated with cellular connectivity 1172 and wireless connectivity 1174. Cellular connectivity 1172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 5G, or other cellular service standards. Wireless connectivity 1174 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1180 include hardware interfaces and connectors, as well as software components (e.g., drivers, protocol stacks) to make peripheral connections. It will be understood that system 1100 could both be a peripheral device (“to” 1182) to other computing devices, as well as have peripheral devices (“from” 1184) connected to it. System 1100 commonly has a “docking” connector to connect to other computing devices for purposes such as managing (e.g., downloading, uploading, changing, synchronizing) content on system 1100. Additionally, a docking connector can allow system 1100 to connect to certain peripherals that allow system 1100 to control content output, for example, to audiovisual or other systems.

In addition to a proprietary docking connector or other proprietary connection hardware, system 1100 can make peripheral connections 1180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

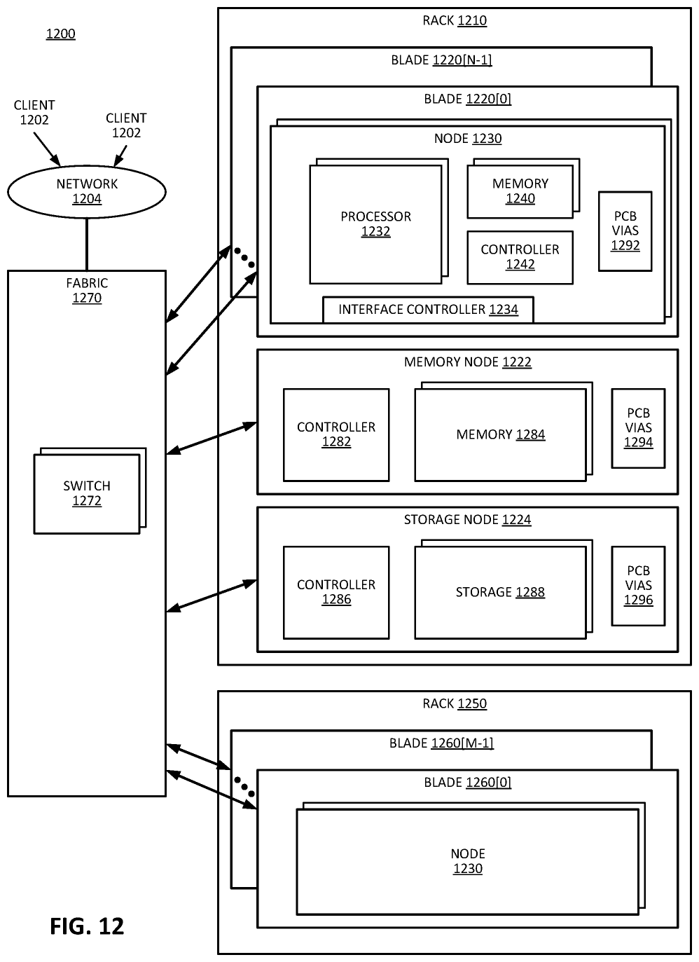

FIG. 12 is a block diagram of an example of a multi-node network in which a circuit board with coils can be implemented. System 1200 represents a network of nodes that can apply adaptive ECC. In one example, system 1200 represents a data center. In one example, system 1200 represents a server farm. In one example, system 1200 represents a data cloud or a processing cloud.

System 1200 includes node 1230, which represents a computer system that includes one or more electronic chips or integrated circuit devices that include System 1100 represents a computer system that includes one or more electronic chips or integrated circuit devices with PCBs that include PCB vias 1292 with planar coils in accordance with any example herein. In one example, memory node 1222 includes PCBs having PCB vias 1294 with planar coils in accordance with any example herein. In one example, storage node 1224 includes PCBs having PCB vias 1296 with planar coils in accordance with any example herein.

One or more clients 1202 make requests over network 1204 to system 1200. Network 1204 represents one or more local networks, or wide area networks, or a combination. Clients 1202 can be human or machine clients, which generate requests for the execution of operations by system 1200. System 1200 executes applications or data computation tasks requested by clients 1202.

In one example, system 1200 includes one or more racks, which represent structural and interconnect resources to house and interconnect multiple computation nodes. In one example, rack 1210 includes multiple nodes 1230. In one example, rack 1210 hosts multiple blade components, blade 1220[0], . . . , blade 1220[N−1], collectively blades 1220. Hosting refers to providing power, structural or mechanical support, and interconnection. Blades 1220 can refer to computing resources on printed circuit boards (PCBs), where a PCB houses the hardware components for one or more nodes 1230. In one example, blades 1220 do not include a chassis or housing or other “box” other than that provided by rack 1210. In one example, blades 1220 include housing with exposed connector to connect into rack 1210. In one example, system 1200 does not include rack 1210, and each blade 1220 includes a chassis or housing that can stack or otherwise reside in close proximity to other blades and allow interconnection of nodes 1230.

System 1200 includes fabric 1270, which represents one or more interconnectors for nodes 1230. In one example, fabric 1270 includes multiple switches 1272 or routers or other hardware to route signals among nodes 1230. Additionally, fabric 1270 can couple system 1200 to network 1204 for access by clients 1202. In addition to routing equipment, fabric 1270 can be considered to include the cables or ports or other hardware equipment to couple nodes 1230 together. In one example, fabric 1270 has one or more associated protocols to manage the routing of signals through system 1200. In one example, the protocol or protocols is at least partly dependent on the hardware equipment used in system 1200.

As illustrated, rack 1210 includes N blades 1220. In one example, in addition to rack 1210, system 1200 includes rack 1250. As illustrated, rack 1250 includes M blade components, blade 1260[0], . . . , blade 1260[M−1], collectively blades 1260. M is not necessarily the same as N; thus, it will be understood that various different hardware equipment components could be used, and coupled together into system 1200 over fabric 1270. Blades 1260 can be the same or similar to blades 1220. Nodes 1230 can be any type of node and are not necessarily all the same type of node. System 1200 is not limited to being homogenous, nor is it limited to not being homogenous.

The nodes in system 1200 can include compute nodes, memory nodes, storage nodes, accelerator nodes, or other nodes. Rack 1210 is represented with memory node 1222 and storage node 1224, which represent shared system memory resources, and shared persistent storage, respectively. One or more nodes of rack 1250 can be a memory node or a storage node.

Nodes 1230 represent examples of compute nodes. For simplicity, only the compute node in blade 1220[0] is illustrated in detail. However, other nodes in system 1200 can be the same or similar. At least some nodes 1230 are computation nodes, with processor (proc) 1232 and memory 1240. A computation node refers to a node with processing resources (e.g., one or more processors) that executes an operating system and can receive and process one or more tasks. In one example, at least some nodes 1230 are server nodes with a server as processing resources represented by processor 1232 and memory 1240.

Memory node 1222 represents an example of a memory node, with system memory external to the compute nodes. Memory nodes can include controller 1282, which represents a processor on the node to manage access to the memory. The memory nodes include memory 1284 as memory resources to be shared among multiple compute nodes.

Storage node 1224 represents an example of a storage server, which refers to a node with more storage resources than a computation node, and rather than having processors for the execution of tasks, a storage server includes processing resources to manage access to the storage nodes within the storage server. Storage nodes can include controller 1286 to manage access to the storage 1288 of the storage node.

In one example, node 1230 includes interface controller 1234, which represents logic to control access by node 1230 to fabric 1270. The logic can include hardware resources to interconnect to the physical interconnection hardware. The logic can include software or firmware logic to manage the interconnection. In one example, interface controller 1234 is or includes a host fabric interface, which can be a fabric interface in accordance with any example described herein. The interface controllers for memory node 1222 and storage node 1224 are not explicitly shown.

Processor 1232 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1240 can be or include memory devices represented by memory 1240 and a memory controller represented by controller 1242.

In general with respect to the descriptions herein, in one aspect, an apparatus includes: a printed circuit board (PCB); a via including a barrel through the PCB, the barrel electrically connected to a pad in a plane of the PCB; and a coil around the pad in the plane of the PCB, the coil of conductor in the plane of the PCB, the coil electrically connected to the pad.

In one example of the apparatus, the PCB further comprises an inner routing layer, wherein the plane comprises the inner routing layer. In accordance with any preceding example of the apparatus, in one example, the plane comprises either a top layer of the PCB or a bottom layer of the PCB. In accordance with any preceding example of the apparatus, in one example, the pad comprises a first pad and the coil comprises a first coil, wherein the first pad and the first coil are in the top layer of the PCB, and further comprising a second pad in the bottom layer of the PCB with a second coil around the second pad in the bottom layer of the PCB. In accordance with any preceding example of the apparatus, in one example, the pad comprises a first pad and the coil comprises a first coil, wherein the first pad and the first coil are in the top layer of the PCB, the PCB further comprising: an inner routing layer including a second pad in a plane of the inner routing layer, with a second coil around the second pad in the inner routing layer. In accordance with any preceding example of the apparatus, in one example, the pad comprises a first pad and the coil comprises a first coil, wherein the first pad and the first coil are in the bottom layer of the PCB, the PCB further comprising: an inner routing layer including a second pad in a plane of the inner routing layer, with a second coil around the second pad in the inner routing layer. In accordance with any preceding example of the apparatus, in one example, the plane comprises a first plane, the pad comprises a first pad, and the coil comprises a first coil, and further comprising a second pad in a second plane of the PCB with a second coil around the second pad in the second plane of the PCB, wherein the first coil and the second coil are coiled in opposite radial directions.

In general with respect to the descriptions herein, in one aspect, a computer system includes: a host processor; and a memory module including multiple memory devices disposed on a printed circuit board (PCB), the PCB including: a via including a barrel through the PCB, the barrel electrically connected to a pad in a plane of the PCB; and a coil around the pad in the plane of the PCB, the coil of conductor in the plane of the PCB, the coil electrically connected to the pad.

In one example of the computer system, the PCB further comprises an inner routing layer, wherein the plane comprises the inner routing layer. In accordance with any preceding example of the computer system, in one example, the plane comprises either a top layer of the PCB or a bottom layer of the PCB. In accordance with any preceding example of the computer system, in one example, the pad comprises a first pad and the coil comprises a first coil, wherein the first pad and the first coil are in the top layer of the PCB, and further comprising a second pad in the bottom layer of the PCB with a second coil around the second pad in the bottom layer of the PCB. In accordance with any preceding example of the computer system, in one example, the pad comprises a first pad and the coil comprises a first coil, wherein the first pad and the first coil are in the top layer of the PCB, the PCB further comprising: an inner routing layer including a second pad in a plane of the inner routing layer, with a second coil around the second pad in the inner routing layer. In accordance with any preceding example of the computer system, in one example, the pad comprises a first pad and the coil comprises a first coil, wherein the first pad and the first coil are in the bottom layer of the PCB, the PCB further comprising: an inner routing layer including a second pad in a plane of the inner routing layer, with a second coil around the second pad in the inner routing layer. In accordance with any preceding example of the computer system, in one example, the plane comprises a first plane, the pad comprises a first pad, and the coil comprises a first coil, and further comprising a second pad in a second plane of the PCB with a second coil around the second pad in the second plane of the PCB, wherein the first coil and the second coil are coiled in opposite radial directions. In accordance with any preceding example of the computer system, in one example, the host processor comprises a multicore processor. In accordance with any preceding example of the computer system, in one example, the computer system includes a display communicatively coupled to the host processor. In accordance with any preceding example of the computer system, in one example, the computer system includes a network interface communicatively coupled to the host processor. In accordance with any preceding example of the computer system, in one example, the computer system includes a battery to power the computer system.

In general with respect to the descriptions herein, in one aspect, a printed circuit board (PCB) includes: multiple planes of routing layers, including a top routing layer, a bottom routing layer, and an inner routing layer between the top routing layer and the bottom routing layer; a via including a barrel through the top routing layer, the inner routing PCB, and the bottom routing layer, the barrel electrically connected to a pad in a first plane of the multiple planes of routing layers; and a coil around the pad in the first plane, the coil of conductor in the first plane, the coil electrically connected to the pad.

In one example of the PCB, the first plane comprises the inner routing layer. In accordance with any preceding example of the PCB, in one example, the first plane comprises either the top routing layer or the bottom routing layer. In accordance with any preceding example of the PCB, in one example, the pad comprises a first pad and the coil comprises a first coil, wherein the first pad and the first coil are in the top routing layer or the bottom routing layer, and further comprising a second pad in the inner routing layer with a second coil around the second pad in the inner routing layer. In accordance with any preceding example of the PCB, in one example, the pad comprises a first pad, and the coil comprises a first coil, and further comprising a second pad in a second plane of the multiple layers, with a second coil around the second pad in the second plane, wherein the first coil and the second coil are coiled in opposite radial directions.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
a printed circuit board (PCB);
a via including a barrel through the PCB, the barrel electrically connected to a pad in a plane of the PCB; and
a coil around the pad in the plane of the PCB, the coil of conductor in the plane of the PCB, the coil electrically connected to the pad.

2. The apparatus of claim 1, wherein the PCB further comprises an inner routing layer, wherein the plane comprises the inner routing layer.

3. The apparatus of claim 1, wherein the plane comprises either a top layer of the PCB or a bottom layer of the PCB.

4. The apparatus of claim 3, wherein the pad comprises a first pad and the coil comprises a first coil, wherein the first pad and the first coil are in the top layer of the PCB, and further comprising a second pad in the bottom layer of the PCB with a second coil around the second pad in the bottom layer of the PCB.

5. The apparatus of claim 3, wherein the pad comprises a first pad and the coil comprises a first coil, wherein the first pad and the first coil are in the top layer of the PCB, the PCB further comprising: an inner routing layer including a second pad in a plane of the inner routing layer, with a second coil around the second pad in the inner routing layer.

6. The apparatus of claim 3, wherein the pad comprises a first pad and the coil comprises a first coil, wherein the first pad and the first coil are in the bottom layer of the PCB, the PCB further comprising: an inner routing layer including a second pad in a plane of the inner routing layer, with a second coil around the second pad in the inner routing layer.

7. The apparatus of claim 1, wherein the plane comprises a first plane, the pad comprises a first pad, and the coil comprises a first coil, and further comprising a second pad in a second plane of the PCB with a second coil around the second pad in the second plane of the PCB, wherein the first coil and the second coil are coiled in opposite radial directions.

8. A computer system, comprising:
a host processor; and
a memory module including multiple memory devices disposed on a printed circuit board (PCB), the PCB including:
a via including a barrel through the PCB, the barrel electrically connected to a pad in a plane of the PCB; and
a coil around the pad in the plane of the PCB, the coil of conductor in the plane of the PCB, the coil electrically connected to the pad.

9. The computer system of claim 8, wherein the PCB further comprises an inner routing layer, wherein the plane comprises the inner routing layer.

10. The computer system of claim 8, wherein the plane comprises either a top layer of the PCB or a bottom layer of the PCB.

11. The computer system of claim 10, wherein the pad comprises a first pad and the coil comprises a first coil, wherein the first pad and the first coil are in the top layer of the PCB, and further comprising a second pad in the bottom layer of the PCB with a second coil around the second pad in the bottom layer of the PCB.

12. The computer system of claim 10, wherein the pad comprises a first pad and the coil comprises a first coil, wherein the first pad and the first coil are in the top layer of the PCB, the PCB further comprising: an inner routing layer including a second pad in a plane of the inner routing layer, with a second coil around the second pad in the inner routing layer.

13. The computer system of claim 10, wherein the pad comprises a first pad and the coil comprises a first coil, wherein the first pad and the first coil are in the bottom layer of the PCB, the PCB further comprising: an inner routing layer including a second pad in a plane of the inner routing layer, with a second coil around the second pad in the inner routing layer.

14. The computer system of claim 8, wherein the plane comprises a first plane, the pad comprises a first pad, and the coil comprises a first coil, and further comprising a second pad in a second plane of the PCB with a second coil around the second pad in the second plane of the PCB, wherein the first coil and the second coil are coiled in opposite radial directions.

15. The computer system of claim 8,
wherein the host processor comprises a multicore processor; or
the computer system further comprising: a display communicatively coupled to the host processor; or
the computer system further comprising: a network interface communicatively coupled to the host processor; or
the computer system further comprising: a battery to power the computer system.

16. A printed circuit board (PCB) comprising:
multiple planes of routing layers, including a top routing layer, a bottom routing layer, and an inner routing layer between the top routing layer and the bottom routing layer;
a via including a barrel through the top routing layer, the inner routing PCB, and the bottom routing layer, the barrel electrically connected to a pad in a first plane of the multiple planes of routing layers; and
a coil around the pad in the first plane, the coil of conductor in the first plane, the coil electrically connected to the pad.

17. The PCB of claim 16, wherein the first plane comprises the inner routing layer.

18. The PCB of claim 16, wherein the first plane comprises either the top routing layer or the bottom routing layer.

19. The PCB of claim 18, wherein the pad comprises a first pad and the coil comprises a first coil, wherein the first pad and the first coil are in the top routing layer or the bottom routing layer, and further comprising a second pad in the inner routing layer with a second coil around the second pad in the inner routing layer.

20. The PCB of claim 16, wherein the pad comprises a first pad, and the coil comprises a first coil, and further comprising a second pad in a second plane of the multiple layers, with a second coil around the second pad in the second plane, wherein the first coil and the second coil are coiled in opposite radial directions.
